(19) United States
(12) Patent Application Publication
(10) Pub. No.: US 2025/0277875 A1
(43) Pub. Date: Sep. 4, 2025

(54) SHORTED LOAD DETECTION USING PWM LOOP

(71) Applicant: SKYWORKS SOLUTIONS, INC., Irvine, CA (US)

(72) Inventor: Mark R. Peting, Yamhill, OR (US)

(21) Appl. No.: 19/066,976

(22) Filed: Feb. 28, 2025

Related U.S. Application Data
(60) Provisional application No. 63/559,314, filed on Feb. 29, 2024.

(51) Int. Cl. G01R 31/52; G01R 31/56

(52) U.S. Cl. CPC G01R 31/52; G01R 31/56

(57) ABSTRACT

A system for detecting short circuits including a driver having a first output and a second output, the driver configured to provide a first voltage to the first output and a second voltage to the second output; a loop filter coupled to the first rail at a first connection and to the second rail at a second connection; a first digital-to-analog converter (DAC) having a first DAC output coupled to the first connection and configured to provide a first DAC current to the first connection, and a second DAC output coupled to the second connection and configured to provide a second DAC current to the second connection; an assist DAC having a first assist output coupled to the loop filter and configured to provide a first assist current and having a second assist output coupled to the loop filter and configured to provide a second assist current; and a controller.

### CROSS REFERENCE TO RELATED APPLICATIONS

This application claims priority under 35 U.S.C. § 119(e) to U.S. Provisional Patent Application 63/559,314, titled “Shorted Load Detection using PWM Loop,” filed on Feb. 29, 2024, which is hereby incorporated by reference in its entirety for all purposes.

### BACKGROUND

### 1. Field of the Disclosure

At least one example in accordance with the present disclosure relates generally to load and short detection in circuits.

### 2. Discussion of Related Art

Amplifiers in devices may be damaged or have their operation impeded by various fault conditions. Some devices may protect amplifiers from fault conditions by shutting the amplifiers off.

### SUMMARY

According to at least one aspect of the present disclosure a system for detecting short circuits is provided the system comprising: a driver having a first output and a second output, the driver configured to provide a first voltage and/or current to the first output and a second voltage and/or current to the second output; a loop filter coupled to the first rail at a first connection and to the second rail at a second connection; a first digital-to-analog converter (DAC) having a first DAC output coupled to the first connection and configured to provide a first DAC voltage and/or current to the first connection, and a second DAC output coupled to the second connection and configured to provide a second DAC voltage and/or current to the second connection; an assist DAC having a first assist output coupled to the loop filter and configured to provide a first assist voltage and/or current and having a second assist output coupled to the loop filter and configured to provide a second assist voltage and/or current; and a controller.

In some examples, the controller is further configured to adjust the output of the first DAC, the second DAC, based on an on resistance and an off resistance. In some examples the controller is configured to determine a value of the off resistance by: determining a first value based on a differential current and a stored value of the off resistance, the differential current being based on currents associated with the first rail and the second rail; and determining a second value based on a common mode voltage and a common mode current, the common mode voltage and the common mode current based on voltages and currents associated with the first rail and the second rail. In some examples, the controller is configured to increase the value of the off resistance responsive to determining that the second value is greater than the first value. In some examples, the controller is configured to decrease the value of the off resistance responsive to determining that the second value is less than the first value. In some examples, the second value is further based on a scaled value of a control voltage and/or current used to control a pulse-width-modulation of the driver. In some examples, the second value is equal to the common mode voltage less the common mode current and plus the scaled value of the control voltage. In some examples, the second value is equal to the common mode voltage less the common mode current. In some examples the first value is equal to a product of the differential current and the stored value of the off resistance. In some examples the controller is configured to determine a value of the on resistance by: determining a first value based on a 100% duty cycle pulse width modulation and an audio drive value; and determining a second value based on the 100% duty cycle pulse width modulation, a non-overlap factor, an ideal duty cycle, and a pulse drive value. In some examples the on resistance is incremented responsive to determining that the second value is greater than the first value. In some examples the on resistance is decremented responsive to determining that the second value is less than the first value. In some examples the first value is further determined based on the non-overlap factor and the ideal duty cycle. In some examples the first value is product of the audio drive and first compositive value, wherein the first composite value is the 100% duty cycle pulse width modulation minus a second composite value, wherein the second composite value is a sum of the ideal duty cycle less a product of the 100% duty cycle pulse width modulation and the non-overlap factor. In some examples the first value of a product of the 100% duty cycle pulse width modulation and the audio drive. In some examples the second value is the pulse drive value times an adjusted drive value, wherein the adjusted drive value is the ideal duty cycle less the product of the 100% duty cycle pulse width modulation and the non-overlap factor.

According to at least one aspect of the present disclosure, a system is provided having a controller configured to perform all the operations of the controller discussed above; memory coupled to the controller; a pulse width modulation controller coupled to the controller and to a driver, the driver being coupled to a load; a loop filter coupled to the driver, an audio digital-to-analog converter (DAC) and an assist DAC, wherein the controller is further configured to control the assist DAC.

According to at least one aspect of the present disclosure, a system is provided having a pulse width modulation controller coupled to a driver, the driver configured to provide pulses, based on control signals from the pulse width modulation controller, to a first rail and a second rail; a load coupled between the first rail and the second rail; a first rail impedance incorporated into the first rail; a second rail impedance incorporated into the second rail; a first digital-to-analog converter (DAC) with a first output coupled to the first rail and a second output coupled to the second rail; a first integrator with a first input coupled to the first rail and a second input coupled to the second rail, and a first output coupled to a third rail, and a second output coupled to a fourth rail; a second integrator with a first input coupled to the third rail and a second input coupled to the fourth rail; an assist DAC with a first output coupled to the third rail and a second output coupled to the fourth rail; and a controller configured to control the assist DAC.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a loop filter system according to an example;

FIG. 2 illustrates a loop filter system according to an example;

FIG. 3A illustrates a process for finding an off resistance according to an example;

FIG. 3B illustrate a process for finding an off resistance according to an example;

FIG. 4A illustrates a process for finding an on resistance according to an example;

FIG. 4B illustrates a process for finding an on resistance according to an example;

FIG. 4C illustrates a process for finding an on resistance according to an example;

FIG. 5A illustrates a process for determining an audio drive according to an example;

FIG. 5B illustrates a process for determining an audio drive according to an example;

FIG. 6 illustrates a chart showing a relationship between the on resistance and off resistance according to an example; and

FIG. 7 illustrates a process for managing a circuit according to an example.

### DETAILED DESCRIPTION

When an amplifier or load experiences a low load impedance (or, more generally, a load impedance that deviates by a threshold amount from an expected value), this may indicate a fault condition (such as a short circuit, overvoltage and/or current condition, and so forth). Low load impedance can cause the amplifier or load to perform poorly or even be damaged. For example, in audio applications, low load impedance may distort or reduce the quality of an audio signal (for example, a signal provided to the ear of a listener). To protect the amplifier or load, and to prevent poor operation of the components of the circuit, examples disclosed herein may shut down the amplifier. The sooner the amplifier is disabled (relative to the fault condition occurring), the less the chance that undesirable conditions, such as damage or poor operation, may occur.

Elements of this disclosure relate generally to rapidly identifying low impedance conditions and disabling affected amplifiers, including identifying said conditions across a wide range of levels (frequencies, phases, amplitudes, channels, and so forth).

Some existing methods may identify a voltage drop across a switching device to detect a low load impedance, with a large drop indicating a low impedance. These methods require extra analog circuitry to measure the voltage drop, and must measure the precise timing during which a pulse is occurring. In multirail systems, the extra circuitry (for measuring voltage drop and timing of the pulse) may need to be replicated for each voltage rail. Furthermore, these methods depend on peak current, which means that accuracy depends on pulse width, and so precise load value determination is difficult.

By contrast, methods and systems disclosed herein do not require extra circuitry, have more robust timing requirements, and are more accurate.

Aspects of the present disclosure involve the use of analog-to-digital converters (ADCs) and digital-to-analog converters (DACs), and digital computation to overcome the limitations of the above-described methods and systems. Consider a system that may operate in closed-loop mode as well as open-loop mode and may even operate in other modes. The system may include one or more drivers being used to drive an output (such as an audio output). The on-resistance (“Ron”) and off-resistance (“Roff”) of the driver may be estimated from the drive signals used to keep the system in a closed-loop state. From this, the ratio of Ron and Roff to the resistance of load (e.g., the “output resistance” or “load impedance”) may be determined. If the load resistance falls outside a given range, the system may determine that a short or fault condition has occurred and take remedial action, such as disabling a portion or all of the system.

In some examples, an analog-to-digital converter (ADC) is used to digitize the output of a loop filter. The digitized output of the loop filter drives pulse-width modulation pulses (PWM pulses) as well as an output audio signal. As a result, digital logic determines the desired pulse width, which is precisely known. Given that the supply voltage is also known, deviations in the pulse width from the desired pulse width may be estimated with precision. As a result, the volt-seconds for each pulse prior to the effect of driver output resistance may be known. Furthermore, if the system is operating in a closed-loop mode, the voltage and/or current on the load may be known. The ratio of these two voltages results from a resistive voltage divider formed by the driver resistance and the load resistance. This ratio may be accurately determined, and may be adjusted for external conditions, such as temperature. Thus, the load impedance may be calculated with the existing circuitry and some digital processing. As the loop filter has high bandwidth and gain, determining the load impedance is fast and accurate over a wide range of signal levels.

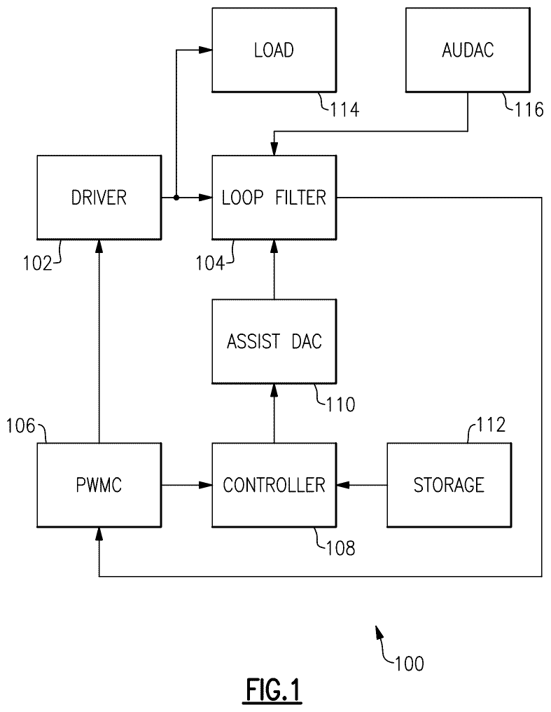

FIG. 1 illustrates a block diagram of a loop-filter system 100 (“system 100”) configured to detect shorts or other fault conditions according to an example. The system 100 includes a driver 102, a loop filter 104, a pulse-width modulation controller 106 (“PWMC 106”), a controller 108, an assist DAC 110, memory and/or storage 112 (“storage 112”), one or more loads 114 (“load 114”), and an audio DAC 116 (“AUDAC 116”).

The driver 102 is coupled to load 114, loop filter 104, and PWMC 106. The loop filter 104 is coupled to at least the driver 102 and PWMC 106, the assist DAC 110, and may be coupled to the load 114. The PWMC 106 is coupled to the driver 102, loop filter 104, and controller 108. The controller 108 is coupled to the PWMC 106, storage 112, and assist DAC 110. The assist DAC 110 is coupled to the controller 108 and loop filter 104. The AUDAC 116 is coupled to the loop filter 104.

The driver 102 can provide an output a voltage or current to the load 114 and loop filter 104. The driver 102 may provide a DC or AC output, may provide the output in pulses (such as square or triangular pulses) having a duration and voltage, and so forth. In some examples, the driver 102 may be an H-bridge or similar device.

The loop filter 104 may process the output from the driver 102. The loop filter 104 may, for example, attenuate or amplify the output or portions of the output (e.g., portions corresponding to given frequencies, phases, amplitudes, and so forth). The loop filter 104 provides an output to the PWMC 106. The output from the loop filter 104 may be a processed version of the output from the driver 102 (e.g., the output that is also provided to the load 114).

The PWMC 106 may control the driver 102. The PWMC 106 may generate a signal indicating when the driver 102 should provide an output and/or may generate a signal indicating when the driver 102 should stop providing an output. In some examples, the PWMC 106 may provide a signal to the driver 102 indicating that the driver 102 should provide an output for a specific duration of time. The PWMC 106 may receive a processed output from the loop filter 104, and may use the processed output from the loop filter 104 to determine how the driver 102 will operate. For example, the PWMC 106 may, based on feedback from the loop filter 104, adjust the signals the PWMC 106 provides to the driver 102, thus causing the driver 102 to provide outputs with different voltage and/or currents, durations, or other characteristics. By controlling the driver 102 to change its output, the feedback (e.g., processed output) from the loop filter 104 may change, and may cause the PWMC 106 to further adjust the behavior of the driver 102. In this way, the PWMC 106 can control the driver 102, based on the feedback from the loop filter 104, to reach and/or maintain a desired state for the system 100 as a whole.

The PWMC 106 can also provide information to the controller 108. For example, the PWMC 106 may provide information indicative of or related to the way the PWMC 106 is adjusting the behavior of the driver 102.

The storage 112 may be RAM, ROM, one time programmable memory (“OTP memory”), registers, and so forth. In some examples, the storage 112 may contain values determined during testing, manufacture, production, or during calibration. The storage 112 may contain predetermined values corresponding to the trim values for the assist DAC 110 current scaling, the resistance (or, more generally, the impedance) of the driver 102, and impedance values corresponding to the impedance of the load under various conditions. The storage 112 may also store other values calculated by the system 100.

The assist DAC 110 may provide an output to the loop filter 104. The assist DAC 110 may convert a digital input to an analog voltage and/or current. The analog voltage and/or current may be provided to the loop filter 104, while the digital input may be received from the controller 108 or another driver that provides a signal to the assist DAC 110, or from the driver 102 (after being converted to digital form by an ADC).

The load 114 may be any type of load, device, or circuit, including audio systems.

The AUDAC 116 is an audio DAC and may provide a voltage or current to the loop filter 104.

The controller 108 controls at least the assist DAC 110. The controller 108 may receive a signal from the PWMC 106 that is indicative of how the PWMC 106 will be or is controlling the driver 102. The controller 108 may also access the storage 112 to retrieve values stored in the storage 112. During operation, the controller 108 may calculate various values and base its control of the assist DAC 110 on the calculated values. For example, during operation the controller 108 may calculate Ron and Roff for each rail of the driver 102 (that is, if driver 102 is an H-bridge topology with multiple rails for voltage and ground, the controller 108 may calculate Ron and Roff for each of those respective rails). The calculation of Ron and Roff for the rails of the driver 102 may be performed using drive signals being used to keep the loop closed. These drive signals may be received from the PWMC 106 and may be indicative of how the PWMC 106 is controlling the driver 102. If the values of Ron and/or Roff deviate from a target value by a threshold amount, the controller 108 may disable the loop-filter system 100 or portions of the system.

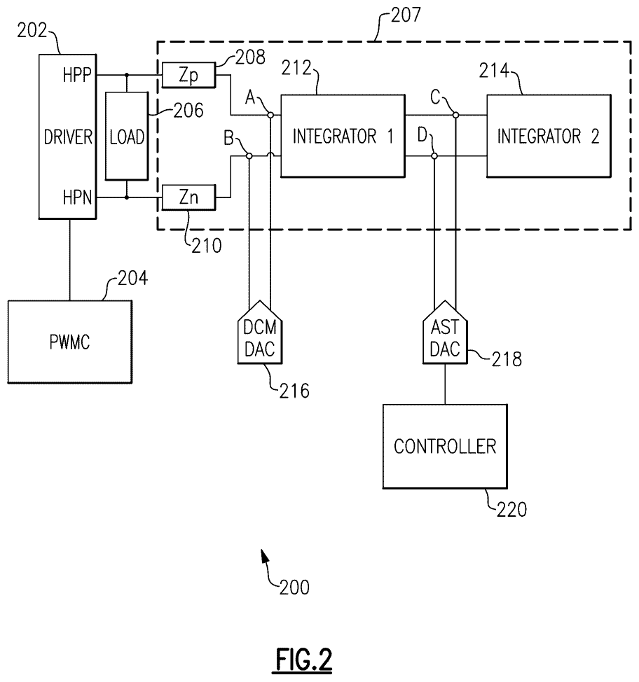

FIG. 2 illustrates a portion of a loop-filter system 200 (“system 200”) according to an example. The system 200 includes a driver 202, a driver controller 204, a load 206, a loop filter 207, a first impedance 208, a second impedance 210, a first integrator 212, a second integrator 214, a differential and common mode DAC 216 (“first DAC 216”), an assist DAC 218 (“second DAC 218”), and a controller 220.

The driver controller 204 is coupled to the driver 202. The driver 202 is coupled at a positive rail to the load 206 and first impedance 208, and at a negative rail to the load 206 and second impedance 210. The load is coupled at a first connection to the positive rail of the driver 202 and to the first impedance 208, and at a second connection to the negative rail of the driver 202 and to the second impedance 210. The first impedance 208 is coupled at a first connection to the positive rail of the driver 202 and to the load 206, and at a second connection to the first integrator and to the first DAC 216. The second impedance 208 is coupled at a first connection to the negative rail of the driver 202 and to the load 206, and at a second connection to the first integrator 212 and to the first DAC 216. The first DAC 216 is coupled at a first connection to the first impedance 208 and the first integrator 212, and at a second connection to the second impedance 210 and the first integrator 212. The first integrator 212 is coupled at a first connection to the first impedance 208 and a first output of the first DAC 216, at a second connection to the second impedance 210 and a second output of the first DAC 216, at a third connection to the second integrator 214 and to a first output of the second DAC 218, and at a fourth connection to the second integrator 214 and a second output of the second DAC 218. The second integrator 214 is coupled at a first connection to the first integrator 212 and the first output of the second DAC 218, and at a second connection to the first integrator 212 and the second output of the second DAC 218. The second DAC 218 is coupled at a first connection to the first integrator 212 and second integrator 214, and at a second connection to a different connection of the first integrator 212 and second integrator 214. The controller 220 is coupled to the second DAC 218.

In general, there are two conducting paths from the driver 202 to the loop filter 207. A first conducting path corresponds to the positive rail of the driver 202, the first impedance 208, and positive inputs and outputs of the first integrator 212 and second integrator 214. A second conducting path corresponds to the negative rail of the driver 202, the second impedance 210, and negative inputs and outputs of the first integrator 212 and second integrator 214. The first DAC 216 is coupled to the first conducting path at one of its outputs, and to the second conducting path at another of its outputs. Likewise, the second DAC 218 is coupled to the first conducting path at one of its outputs, and to the second conducting path at another of its outputs.

The driver 202 has at least one positive rail and at least one negative rail. The driver 202 provides an output voltage or current to at least one of the rails, and may provide output voltages or currents to any number of the positive and negative rails at any time. The driver 202 is controlled by the driver controller 204. The driver controller 204 may be a pulse-width-modulation controller.

The load 206 may use current or voltages provided by the driver 202 to operate.

The first impedance 208 may have a resistance and/or reactance. The second impedance 210 may have a resistance and/or reactance as well. In some examples, the first impedance 208 and second impedance 210 have equal resistances and/or reactances, and in some examples they have different resistance and/or reactances.

The first integrator 212 and second integrator 214 may be types of amplifiers that amplify or attenuate input voltages and/or currents. The first integrator 212 and second integrator 214 may have differential inputs and may provide differential outputs.

The first DAC 216 can provide a current and/or voltage to the first conducting path at a point between the first impedance 208 and the first integrator 212, and to the second conducting path at a point between the second impedance 208 and the first integrator 212. The first DAC 216 may provide a differential current and/or a common mode current.

The second DAC 218 can provide a current and/or voltage to the first conducting path at a point between the first integrator 212 and second integrator 214, and to the second conducting path at a point between the first integrator 212 and the second integrator 214.

In some examples, where the driver 202 has multiple positive rails and/or negative rails, the first DAC 216 and/or second DAC 218 may include connections to conducting paths corresponding to each of those rails.

The controller 220 may determine Ron and Roff for each of the positive and negative rails of the driver 202, and may determine if a fault condition exists. In some examples, the controller 220 may determine Roff based on one or more of the differential current, common mode current, common mode input to the first integrator 212, voltage rail values, and/or predetermined values. In some examples, the controller 220 may determine Ron based on one or more of various drive values (e.g., voltage and/or currents or currents provided by the driver 202), a 100% duty cycle, an actual duty cycle, and an ideal duty cycle.

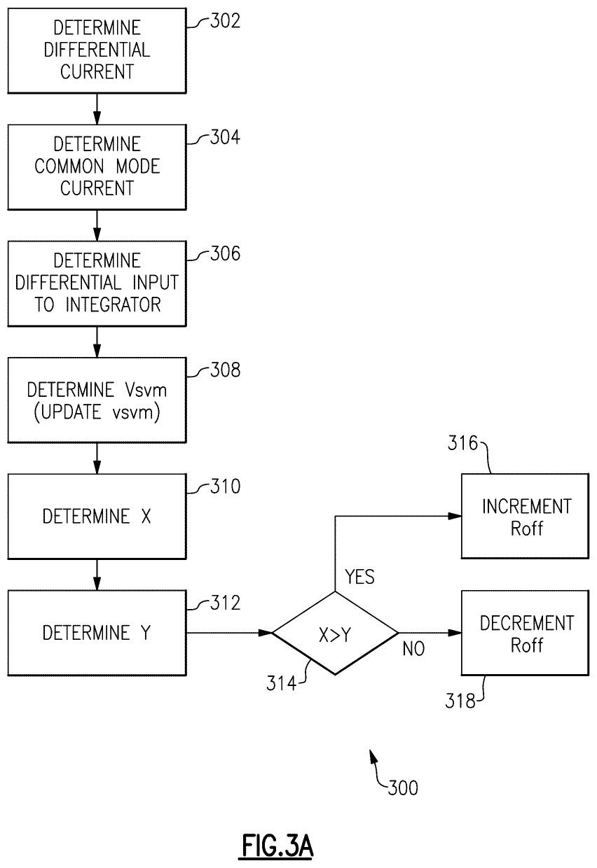

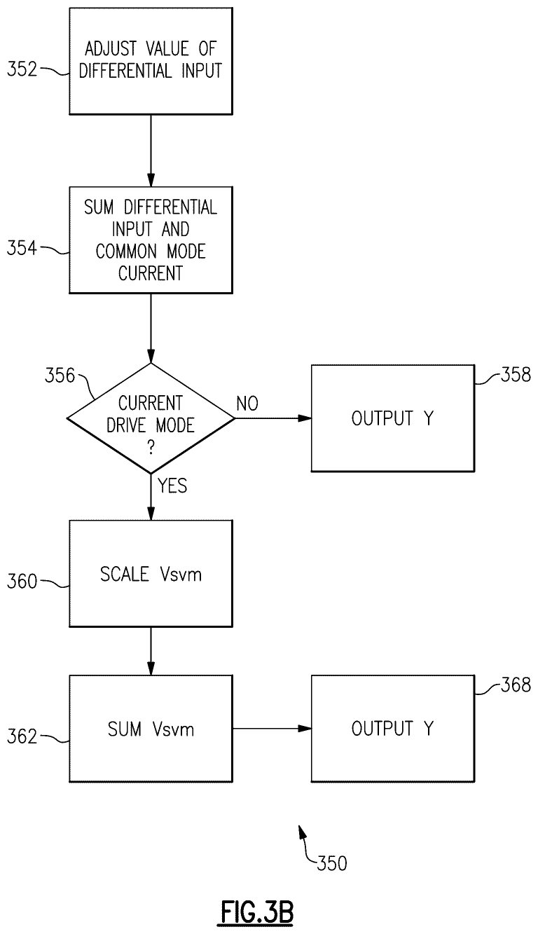

FIG. 3A illustrates a process 300 for determining Roff according to an example. Reference will be made to FIG. 2 in discussion of the process 300.

At act 302, the controller 220 determines the differential current provided by the first DAC 216. The controller 220 may determine the differential current directly (e.g., using a current sensor), or may receive a value from the first DAC 216 or a controller of the first DAC 216 which indicates the value of the differential current. The process 300 may then continue to act 304.

At act 304, the controller 220 determines the common mode current provided by the first DAC 216. The controller 220 may determine the common mode current directly (e.g., using a current sensor), or may receive a value from the first DAC 216 or a controller of the first DAC 216 which indicates the value of the common mode current. The process 300 may then continue to act 306.

At act 306, the controller 220 determines the differential input to an integrator. In some examples, the differential input may be related to the voltage and/or current provided on the second conducting path to the first integrator 212 (e.g., the voltage and/or current at node B in FIG. 2). In some examples, the controller 220 may determine the differential input as the value of the voltage and/or current at node B divided by the impedance of the second impedance 210. In some examples, the voltage and/or current at node A divided by the impedance of the first impedance 208 may be used. Once the differential input has been determined, the process 300 may proceed to act 308.

At act 308, the controller 220 may determine the voltage (Vsvm) used to control the PWM cycle of driver 202. The process 300 may then proceed to act 310.

At act 310, the controller 220 may determine a value, referred to as “X,” which may be used to determine whether and how to change Roff. In some examples, X may be determined based on the differential input, the common mode current, and/or Vsvm. One example of how to determine X is provided in FIG. 3B. The process 300 may then continue to act 312.

At act 312, the controller 220 may determine a value, referred to as “Y,” which may be used to determine whether and how to change Roff. In some examples, Y may be determined based on the differential current and a value (for example, the current value) of Roff. In some examples, Y may be determined as a product of the differential current and a value of Roff. The process 300 may then continue to act 314.

At act 314, the controller 220 determines if X is greater than Y. In some examples, the controller 220 may determine if X is equal to Y as well. If the controller 220 determines that X is greater than Y (314 YES), the process 300 may continue to act 316. If the controller 220 determines that X is less than (or in some examples, less than or equal to) Y (314 NO), the process 300 may continue to act 318.

At act 316, the value of Roff may be incremented by a set amount equal to or greater than a set value, for example 1 or 0.5. In some examples, the controller 220 may control the incrementing of the value of Roff stored in memory (such as a register).

At act 318, the value of Roff may be decremented by a set amount equal to or greater than 1. In some examples, the controller 220 may control the decrementing of the value of Roff stored in memory (such as a register).

FIG. 3B illustrates a process 350 for determining the value of “X” discussed with respect to act 310 of FIG. 3A according to an example.

At act 352, the controller 220 adjusts the value of the common mode voltage (Vcm). In some examples, the controller 220 may multiply the value of Vcm by a constant, such as 1 or −1, based on the operating mode of the loop filter system 200. For example, in a positive current drive mode the controller 220 may multiply the value of Vcm by −1, while in other operating modes the controller 220 may multiply the value of Vcm by 1. The process 350 may then continue to act 354.

At act 354, the controller 220 determines the sum of Vcm (as adjusted in act 352) and the common mode current (Icm) by subtracting the common mode current from Vcm. That is, the controller 220 may determine the value of (Vcm−Icm). The process 350 may then continue to act 356.

At act 356, the controller 220 may determine if the loop filter system 200 is operating in a positive current drive mode or a different mode. If the controller 220 determines that the loop filter system 200 is operating in a positive current drive mode (356 YES), the process 350 may continue to act 360. If the controller 220 determines that the loop filter system 200 is not operating in a positive current drive mode (356 NO), the process 350 may continue to act 358.

At act 358, the controller 220 finalizes the value of X. In some examples, X may equal the difference between Vcm and Icm: that is, X may equal (Vcm−Icm). The process may then end.

Returning to act 356, as stated above, the process may continue to act 360 if the controller 220 determines that the loop filter system 200 is operating a positive current drive mode (356 YES).

At act 360, the controller 220 may scale Vsvm by a constant. The constant may be preset and/or stored in memory, and may be based on characteristics of the second DAC 218. The scaling constant may be greater than or equal to zero. The process 350 may then continue to act 362.

At act 362, the scaled value of Vsvm is summed together by the controller 220 with the sum of Vcm and Icm. For example, the scaled value of Vsvm may be added to the sum of the differential input and common mode current, as expressed by the equation: Vcm−Icm+Vscaled, where Vscaled is the scaled value of Vsvm. The process 350 may then continue to act 368.

At act 368, the controller 220 finalizes the value of X. In some examples, X may equal the difference between the differential input and the common mode current further summed together with the scaled value of Vsvm: that is, X may equal Vcm−Icm+Vscaled.

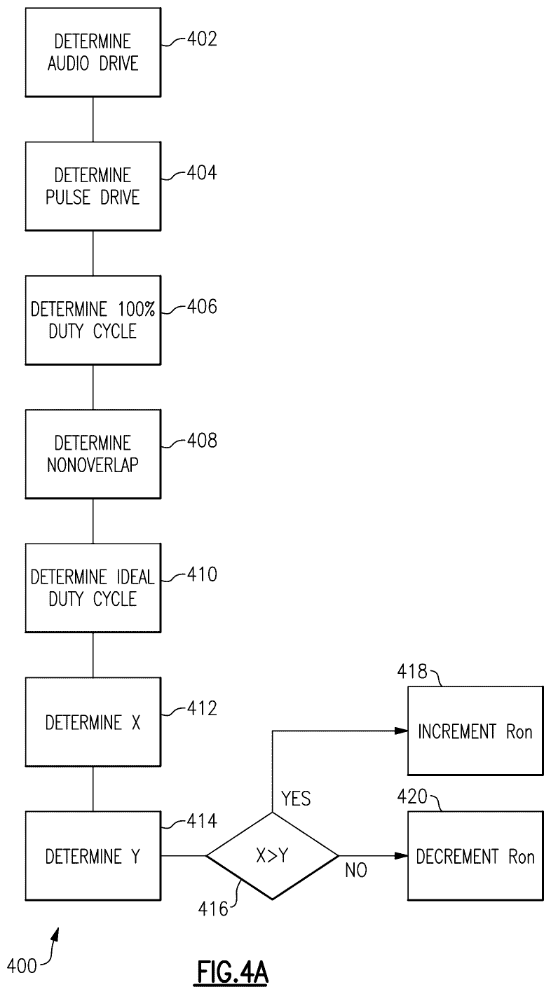

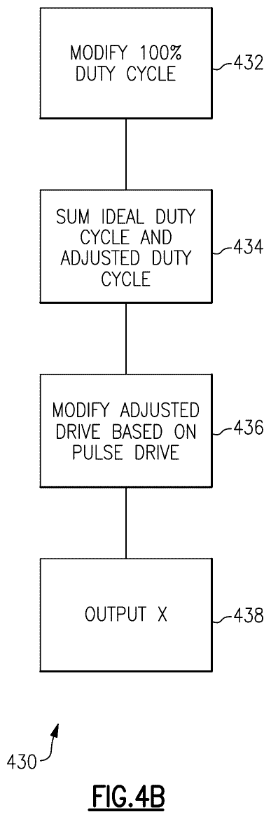

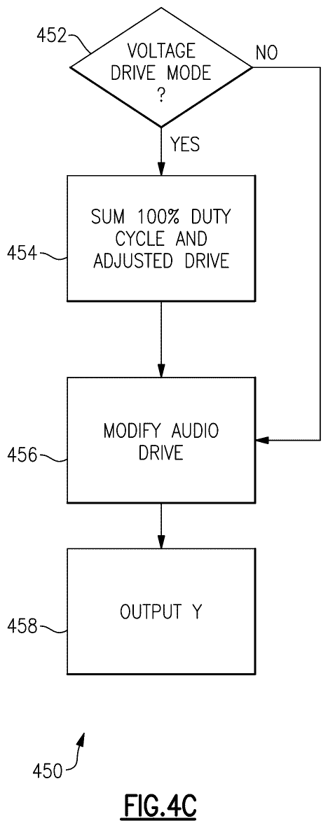

FIG. 4A illustrates a process 400 for determining the value of Ron according to an example.

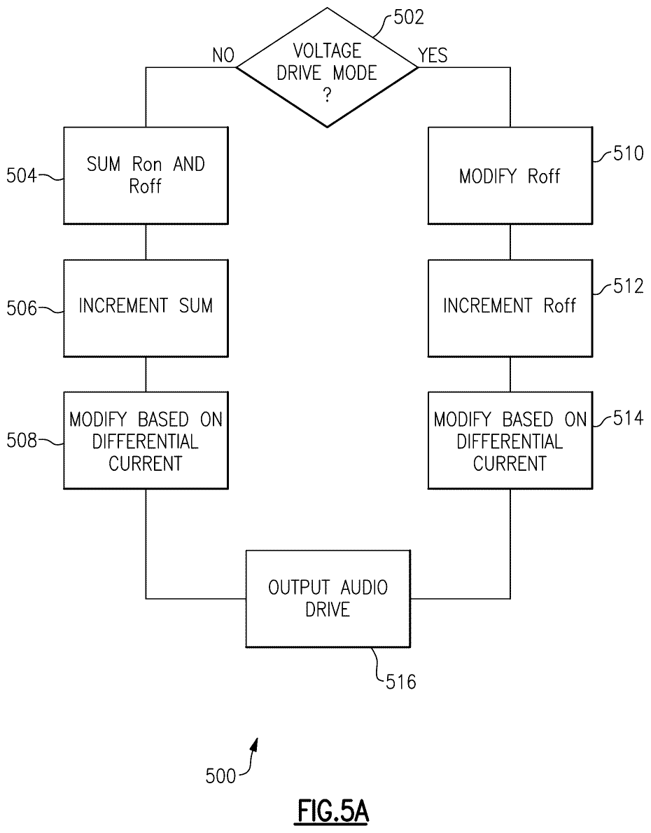

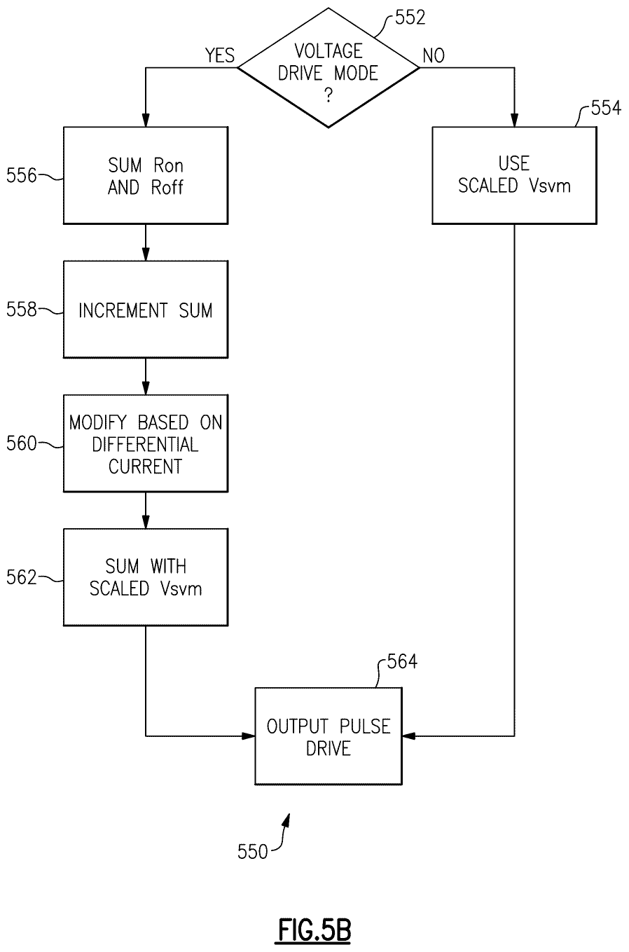

At act 402, the controller 220 determines the audio drive. The controller may determine the audio drive based on Ron and/or Roff, the differential current, and the scaled value of Vsvm. In some examples, the value of the audio drive may depend on the operating mode of the system. A more detailed discussion of one method of how to calculate audio drive is presented with respect to FIG. 5A. The process 400 may then continue to act 404.

At act 404, the controller 220 determines the pulse drive. The controller may determine the pulse drive based on Ron and/or Roff, the differential current, and the scaled value of Vsvm. In some examples, the value of the pulse drive may depend on the operating mode of the system. A more detailed discussion of one method of how to calculate pulse drive is presented with respect to FIG. 5B. The process 400 may then continue to act 406.

At act 406, the controller 220 determines the amount of energy provided by the driver 202 during a 100% on duty cycle. The controller may determine the amount of energy provided during a 100% duty cycle by determining the voltage and/or current and/or charge delivered, and/or based on predetermined constants and time, and so forth. The process 400 may then continue to act 408.

At act 408, the controller 220 determines the nonoverlap interval for the driver 202. That is, the driver 202 may have a finite turn on and turn off time, and thus may not reach full power instantaneously. For example, the voltage and/or current provided by the driver 202 may increase over a, usually short, period of time. The nonoverlap interval is an indication of the amount of time it takes for the driver 202 to turn on and off. The nonoverlap interval may be expressed as the percentage of time (of a 100% duty cycle, for example) that it takes the driver 202 to turn on, or it may be expressed a proportion of the time the driver is on compared to the total time or a proportion of the time the driver is off compared to the total time, or in any other desired way. Each of these expressions can indicate the amount of time the driver 202 is operating in a given mode (e.g., off, on, or ramping up/down from on to off). Once the nonoverlap interval is determined, the process 400 may continue to act 410.

At act 410, the controller 220 determines an ideal duty cycle. The ideal duty cycle may be the duty cycle for the driver 202 that would reflect a desired duty cycle assuming no turn-on or turn-off time (e.g., assuming that, once the driver 202 is activated, the driver 202 immediately reaches maximum output, and that once the driver 202 is deactivated, the driver 202 immediately ceases any output, without a finite ramp up or ramp down time). The process 400 may then continue to act 412.

At act 412, the controller 220 determines X. In some examples, the controller 220 may determine X based on the pulse drive, nonoverlap interval, 100% duty cycle, and/or ideal duty cycle. A process for determining X is discussed in greater detail with respect to FIG. 4B. Once the controller 220 determines X, the process 400 may continue to act 414.

At act 414, the controller determines Y. In some examples, the controller 220 may determine Y based on the 100% duty cycle, nonoverlap interval, ideal duty cycle, audio drive, and/or operating mode. A process for determining Y is discussed in greater detail with respect to FIG. 4C. Once the controller 220 determines Y, the process 400 may continue to act 416.

At act 416, the controller 220 determines if X is greater than Y. In some examples, the controller 220 may determine if X is equal to Y as well. If the controller 220 determines that X is greater than Y (416 YES), the process 300 may continue to act 418. If the controller 220 determines that X is less than (or in some examples, less than or equal to) Y (416 NO), the process 300 may continue to act 420.

At act 418, the value of Ron may be incremented by a set amount equal to or greater than a set value, for example 1 or 0.5. In some examples, the controller 220 may control the increment of the value of Ron stored in memory (such as a register).

At act 420, the value of Ron may be decremented by a set amount equal to or greater than a set value, for example 1 or 0.5. In some examples, the controller 220 may control the decrement of the value of Ron stored in memory (such as a register).

FIG. 4B illustrates a process 430 for determining a value of X (such as during act 412 of process 400 of FIG. 4A) according to an example.

At act 432, the controller 220 may adjust the 100% duty cycle based on the nonoverlap interval. For example, the nonoverlap interval may be a value expressing a finite turn-on or turn-off time for the driver 202. The nonoverlap interval may therefore, in some examples, be a value between 0 and 1, with 1 indicating that the driver 202 turns on instantaneously, and 0 indicating that the driver 202 never turns on. The 100% duty cycle may be multiplied by the nonoverlap interval to produce an adjusted duty cycle. The process 430 may then continue to act 434.

At act 434, the controller 220 may sum together the adjusted duty cycle and the ideal duty cycle to produce the adjusted drive value. In some examples, the adjusted duty cycle is subtracted from the ideal duty cycle. The process 430 may then continue to act 436.

At act 436, the controller 220 may modify the adjusted drive value by the pulse drive. In some examples, the adjusted drive value and the pulse drive may be multiplied together. The process 430 may then continue to act 438.

At act 438, the controller 220 may output the value of X based on the previous acts 432-436. In some examples, X=(DC_{ideal}−(DC_{100%}·n))·Dₚᵤₗₛₑ), where DC_{100%} is the 100% duty cycle, n is the nonoverlap interval, DC_{ideal} is the ideal duty cycle, and Dₚᵤₗₛₑ is the pulse drive.

FIG. 4C illustrates a process 450 for determining a value of Y (such as during act 414 of process 400 of FIG. 4A) according to an example.

At act 452, the controller 220 determines whether the system is operating in a voltage drive mode or a current drive mode. If the controller 220 determines that the system is operating in a voltage drive mode (452 YES), the process 450 may continue to act 454. If the controller 220 determines that the system is not operating in a voltage drive mode (452 NO), the process 450 may continue to act 456.

At act 454, the controller 220 sums the 100% duty cycle with the adjusted drive value. The adjusted drive value may be the same as the adjusted drive value determined during act 434 of process 430 of FIG. 4B. In some examples, the controller 220 may subtract the adjusted drive value from the 100% duty cycle to produce the adjusted 100% duty cycle. The process 450 may then continue to act 456.

At act 456, the controller 220 may modify the audio drive by either the 100% duty cycle, or the adjusted 100% duty cycle. For example, the controller 220 may multiply the audio drive by the 100% duty cycle in some modes of operation (such as non-voltage drive modes of operation), or may multiply the audio drive by the adjusted 100% duty cycle in some modes of operation (such as voltage drive modes of operation). The process 450 may then continue to act 458.

At act 458, the controller 220 may output the value of Y based on the previous acts 452-456. In some examples, Y=DC_{100%}·AD, where DC_{100%} is the 100% duty cycle and AD is the audio drive. In some examples, Y=((DC_{100%}−Adj)·AD), where Adj is the adjusted drive value.

FIG. 5A illustrates a process 500 for determining the audio drive according to an example.

At act 502, the controller 220 determines the mode of operation of the system. In some examples, the controller 220 determines whether the system is in a voltage drive or current drive mode of operation. If the controller 220 determines that the system is in a voltage drive mode of operation (502 YES), the process 500 continue to act 510. If the controller 220 determines the system is not in a voltage drive mode of operation (502 NO), the process 500 continues to act 504.

At act 504, the controller 220 sums Ron and Roff to produce a summed value using whatever value of Ron and Roff is currently available (e.g., the most recently determined values for Ron and Roff). In some examples, the controller 504 may add Roff to Ron. The process 500 then continues to act 506.

At act 506, the controller 220 increments the summed value. In some examples the controller 220 increments the summed value by a constant amount. In some examples, the constant amount is 1, and in other examples, the constant amount may be any value greater than or equal to zero. The process 500 may then continue to act 508.

At act 508, the controller 220 modifies the summed value based on the differential current. In some examples, the controller 220 multiples the summed value by the differential current value. The process 500 may then continue to act 516.

At act 510, the controller 220 modifies Roff. In some examples, the controller 220 may modify Roff by multiplying Roff by a constant value. In some examples, the constant value is 2. In some examples, the constant value may be any value greater than or equal to zero. The process 500 may then continue to act 512.

At act 512, the controller 220 increments Roff. In some examples, the controller 220 may increment Roff by a constant value. In some examples, the constant value is 1. In some examples, the constant value may be any value greater than or equal to zero. The process 500 may then continue to act 514.

At act 514, the controller 220 modifies Roff based on the value of the differential current. In some examples, the controller 220 may multiply Roff and the value of the differential current together. The process 500 may then continue to act 516.

At act 516, the controller outputs the audio drive value. In some examples, the audio drive value may equal the value determined during act 508. In some examples, the audio drive value may equal the value determined during act 514. For example, the value determined during act 508 may be used when the system does not operate in a voltage drive mode, while the value determined during act 514 may be used when the system is operating in a voltage drive mode. For example, in a voltage drive mode the following equation may provide the audio drive value: AD=(((R_{off}·m)+n)·I_{diff}), where R_{off} is Roff, AD is the audio drive, m is a first constant, n is a second constant, and I_{diff} is the differential current. For example, in a mode other than a voltage drive mode the following equation may provide the audio drive value: AD=(((Rₒₙ+R_{off})+n)·I_{diff}), where Rₒₙ is Ron.

FIG. 5B illustrates a process 550 for determining the pulse drive according to an example.

At act 552, the controller 220 determines whether the system is in a voltage drive mode of operation. If the controller 220 determines that the system is in a voltage drive mode of operation (552 YES), the process 550 may continue to act 556. If the controller 220 determines that the system is not in a voltage drive mode of operation (552 NO), the process 550 may continue to act 554.

At act 554, the controller 220 determines the scaled Vsvm. The process 550 may then continue to act 564.

At act 556, the controller 220 may determine a sum of Ron and Roff to produce a summed value. In some examples, the controller 220 may add Ron and Roff together. The controller 550 may use a most recent value of Ron and a most recent value of Roff or whichever values of Ron and Roff are currently available. The process 550 may then continue to act 558.

At act 558, the controller 220 may increment the summed value by a constant amount. In some examples, the constant amount is 1. In some examples, the constant amount is any amount greater than or equal to zero. The process 550 may then continue to act 560.

At act 560, the controller 220 may modify the summed value based on the differential current. In some examples, the controller 220 may multiply the summed value and the differential current together to produce a product. The process 550 may then continue to act 562.

At act 562, the controller 220 may sum together the product and the scaled Vsvm. In some examples, the controller 220 may subtract the product from the scaled Vsvm. The process 550 may then continue to act 564.

At act 564, the controller 220 may provide the pulse drive. In some examples, the pulse drive value may be based on just the scaled Vsvm value (e.g., when the system is not in a voltage drive mode). For example, the following equation may express the value of the pulse drive: PD=V_{scaled}, where PD is the pulse drive and V_{scaled} is scaled Vsvm. In some examples, the pulse drive may be based on Ron, Roff, scaled Vsvm, and the differential current. For example, the following equation may express the value of the pulse drive: PD=V_{scaled}−I_{diff}·((Rₒₙ+R_{off})+n), where Rₒₙ is Ron, R_{off} is Roff, n is a constant value, and I_{diff} is the differential current.

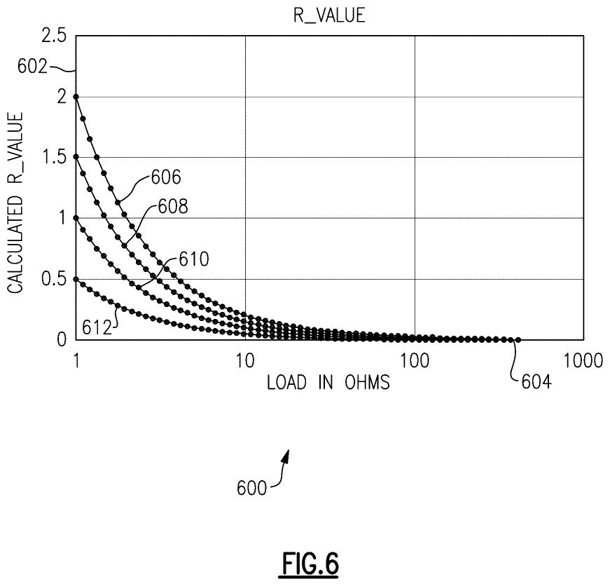

FIG. 6 illustrates a chart 600 showing the relationship between the calculated Ron or Roff value and the resistance of the load in Ohms, according to an example. The chart 600 includes a first axis 602, a second axis 604, a first trace 606, a second trace 608, a third trace 610, and a fourth trace 612.

The first axis 602 corresponds to the calculated value of either Ron or Roff (whichever is being used). The second axis 604 corresponds to the resistance of the load in Ohms. Note the second axis 604 is a logarithmic scale, where each tick along the second axis 604 represents an increase in the order of magnitude (thus, the first tick is 1, the second 10, the third 100, and the fourth is 1000).

The first trace 606 corresponds to a driver having a resistance of 2 Ohms. The second trace 608 corresponds to a driver having a resistance of 1.5 Ohms. The third trace 610 corresponds to a driver having a resistance of 1 Ohm. The fourth trace 612 corresponds to a driver having a resistance of 0.5 Ohms. However, these resistances are purely for explanatory purposes, and could be any value (or could be impedances having complex components).

The resistance of the driver may be stored in memory and may be determined prior to use (e.g., during testing of a particular device using the systems and methods discussed herein or using a driver such as driver 202).

Consider an example where the load is 16 Ohms. For the third trace 610, prior to use (e.g., during testing), the value of the third trace 610 may be approximately 0.105 at 16 Ohms of nominal load resistance. Suppose a threshold of 10 Ohms is used. At what value should the controller 220 consider a short to have occurred? In this example, a value for Ron or Roff (whichever is being used) should be 0.168. That is, Ron or Roff should remain above 0.168. This value may be determined by the equation:

$${T}_{fault} = {OTP}_{driver} \cdot \frac{{T}_{Ohms}}{{OTP}_{Ohms}} \qquad ( 1 )$$

In equation (1), above, T_{fault} is the value above which Ron or Roff should remain. If Ron or Roff fall below T_{fault}, this may indicate that a short or other fault condition has occurred. OTP_{driver} indicates a value, stored in memory and determined prior to use (e.g., during testing) of Ron or Roff at a nominal load of k Ohms, where k may be chosen as any value and was chosen as 16 Ohms in the foregoing example. Tₒₕₘₛ indicates the threshold in Ohms; in the foregoing example, it was chosen as 10 Ohms. OTPₒₕₘₛ

In general, since Ron and Roff represent a ratio of resistances, specifically the resistance of the driver to the resistance of the load, it is possible to calculate the level of resistance of the driver at a given moment in time by comparing Ron or Roff to the load in Ohms and working backwards to determine the driver resistance. If the driver resistance is too low (e.g., if Ron or Roff is too low when expressed as driver resistance over total resistance and/or load resistance), then this may indicate a short or other fault condition.

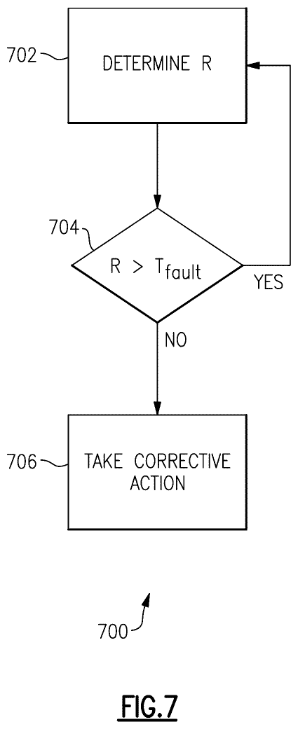

FIG. 7 illustrates a process 700 for managing a circuit using the techniques and systems described herein.

At act 702, a controller determines a resistance, R, where R may be at least one or Ron or Roff. To determine Ron and/or Roff, the controller may implement physical hardware, physical hardware and software, or software to perform the techniques for determining Ron and Roff disclosed here. For example, the controller may implement the processes 300, 350, 400, 430, 450, 500, 550 of FIGS. 3A, 3B, 4A, 4B, 4C, 5A, and/or 5B described herein. The process 700 may then continue to act 704.

At act 704, the controller determines whether R is greater than or less than a threshold value. If R is greater than the threshold value, the process 700 may return to act 702 and determine R again at a future time (704 YES). Prior to returning to act 702, the controller may perform other operations as well. If R is less than the threshold value, the process 700 may continue to act 706 (704 NO).

At act 706, the controller may take corrective action. For example, the controller may determine that, since R is less than the threshold value, a fault has occurred. Accordingly, the controller may raise an alarm (e.g., physical, auditory, readable, visual, and so forth) to alert a user or another apparatus of the fault condition, or may attempt to protect the circuit by cutting power, reducing power use, temporary pausing operation of the circuit, and so forth.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the controller 108, may execute various operations discussed above. Using data stored in associated memory and/or storage, the controller 108 also executes one or more instructions stored on one or more non-transitory computer-readable media, which the controller 108 may include and/or be coupled to, that may result in manipulated data. In some examples, the controller 108 may include one or more processors or other types of controllers. In one example, the controller 108 is or includes at least one processor. In another example, the controller 108 performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A system for detecting fault conditions, the system comprising:
a driver having a first rail and a second rail, the driver configured to provide a first voltage to the first rail and a second voltage to the second rail;
a loop filter coupled to the first rail at a first connection and to the second rail at a second connection;
a first digital-to-analog converter (DAC) having a first DAC output coupled to the first connection and configured to provide a first DAC current to the first connection, and having a second DAC output coupled to the second connection and configured to provide a second DAC current to the second connection; and
an assist DAC having a first assist output coupled to the loop filter and configured to provide a first assist current and having a second assist output coupled to the loop filter and configured to provide a second assist current.

2. The system of claim 1 wherein the system further comprises a controller and the controller is configured to adjust the output of the first DAC based on an on resistance and an off resistance.

3. The system of claim 2 wherein the controller is further configured to determine a value of the off resistance by:
determining a first value based on a differential current and a stored value of the off resistance, the differential current being based on currents associated with the first rail and the second rail; and
determining a second value based on a common mode voltage and a common mode current, the common mode voltage and the common mode current based on voltages and currents associated with the first rail and the second rail.

4. The system of claim 3 wherein the controller is configured to increase the value of the off resistance responsive to determining that the second value is greater than the first value.

5. The system of claim 3 wherein the controller is configured to decrease the value of the off resistance responsive to determining that the second value is less than the first value.

6. The system of claim 3 wherein the second value is further based on a scaled value of a control voltage used to control a pulse-width-modulation of the driver.

7. The system of claim 6 wherein the second value is equal to the common mode voltage less the common mode current and plus the scaled value of the control voltage.

8. The system of claim 3 wherein the second value is equal to the common mode voltage less the common mode current.

9. The system of claim 3 wherein the first value is equal to a product of the differential current and the stored value of the off resistance.

10. The system of claim 2 wherein the controller is configured to determine a value of the on resistance by:
determining a first value based on a 100% duty cycle pulse width modulation and an audio drive value; and
determining a second value based on the 100% duty cycle pulse width modulation, a non-overlap factor, an ideal duty cycle, and a pulse drive value.

11. The system of claim 10 wherein the on resistance is incremented responsive to determining that the second value is greater than the first value.

12. The system of claim 10 wherein the on resistance is decremented responsive to determining that the second value is less than the first value.

13. The system of claim 10 wherein the first value is further determined based on the non-overlap factor and the ideal duty cycle.

14. The system of claim 13 wherein the first value is product of the audio drive and first compositive value, wherein the first composite value is the 100% duty cycle pulse width modulation minus a second composite value, wherein the second composite value is a sum of the ideal duty cycle less a product of the 100% duty cycle pulse width modulation and the non-overlap factor.

15. The system of claim 10 wherein the first value of a product of the 100% duty cycle pulse width modulation and the audio drive.

16. The system of claim 10 wherein the second value is the pulse drive value times an adjusted drive value, wherein the adjusted drive value is the ideal duty cycle less the product of the 100% duty cycle pulse width modulation and the non-overlap factor.

17. A method of detecting and addressing a fault condition in a circuit, comprising:
determining a resistance based on at least one of an on resistance or an off resistance;
comparing the resistance to a threshold value;
determining that a fault has occurred responsive to determining that the resistance is less than the threshold value; and
providing an alert signal indicating that the resistance is less than the threshold value.

18. The method of claim 17 further comprising determining a present value of the off resistance by
determining a differential current value provided by a first digital-to-analog converter (“first DAC”);
determining a common mode current;
determining a differential input to an integrator;
determining a voltage used to control a pulse-width modulation cycle of a driver;
determining a first value based on at least one of the differential input, the common mode current, or the common mode voltage;
determining a second value based on at least one of the differential current and a predetermined off-resistance value;
increasing the present value of the off resistance responsive to determining that the first value is greater than the second value; and
decreasing the present value of the off resistance responsive to determining that the first value is not greater than the second value.

19. The method of claim 18 wherein the first value is determined based on a difference between a common mode voltage and the common mode current and the second value is based on a sum of a first duty cycle and an adjusted drive value.

20. The method of claim 17 wherein determining a present value of the on resistance by
determining an audio drive value;
determining an operating mode;
determining a pulse drive value;
determining a first duty cycle;
determining a nonoverlap interval;
determining an ideal duty cycle;
determining a first value based on at least one of the pulse drive value, the nonoverlap interval, the first duty cycle, or the ideal duty cycle;
determining a second value based on at least one of the audio drive value, the operating mode, the pulse drive value, the first duty cycle, the nonoverlap interval, the ideal duty cycle;
increasing the present value of the on resistance responsive to determining that the first value is greater than the second value; and
decreasing the present value of the on resistance responsive to determining that the first value is not greater than the second value.
